(19) United States
(12) Patent Application Publication
(10) Pub. No.: US 2026/0231385 A1
(43) Pub. Date: Aug. 6, 2026

(54) GATE ISOLATION FEATURES FOR MEMORY AND LOGIC DEVICES

(71) Applicant: Taiwan Semiconductor Manufacturing Company, Ltd., Hsinchu (TW)

(72) Inventors: Ping-En Cheng, Hsinchu (TW); Chih-Hsuan Chen, Hsinchu (TW); Ping-Wei Wang, Hsin-Chu (TW); Jui-Lin Chen, Taipei City (TW)

(21) Appl. No.: 19/042,884

(22) Filed: Jan. 31, 2025

(51) Int. Cl. H10B 10/00

(52) U.S. Cl. CPC H10B 10/125

(57) ABSTRACT

A semiconductor structure according to the present disclosure includes a first active region and a second active region, a first gate structure disposed over the first active region, a second gate structure disposed over the second active region, and a gate isolation feature sandwiched between a sidewall of the first gate structure and a sidewall of the second gate structure. The gate isolation feature includes a first dielectric layer interfacing the sidewall of the first gate structure and the sidewall of the second gate structure, a diffusion barrier liner interfacing the first dielectric layer, and a second dielectric layer interfacing the diffusion barrier liner. The second dielectric layer is spaced apart from the first dielectric layer by the diffusion barrier liner.

### PRIORITY DATA

This application claims priority to U.S. Provisional Patent Application No. 63/711,905, filed on Oct. 25, 2024, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFET) where an n-type multi-gate transistor and a p-type multi-gate transistor are stacked vertically, one over the other. While existing CFET structures and fabrication processes are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a layout of a top device layer of an example 6-transistor (6T) static random access memory (SRAM) cell implemented with a CFET construction, according to one or more aspects of the present disclosure.

FIG. 2 illustrates a layout of a bottom device layer of an example 6T SRAM cell implemented with a CFET construction, according to one or more aspects of the present disclosure.

FIG. 3 illustrates a layout of a top device layer of a logic standard cell implemented with a CFET construction, according to one or more aspects of the present disclosure.

FIG. 4 illustrates a layout of a bottom device layer of a logic standard cell implemented with a CFET construction, according to one or more aspects of the present disclosure.

FIG. 5 illustrates a fragmentary cross-sectional view along line A-A in FIGS. 1, 2, 3, or 4, according to one or more aspects of the present disclosure.

FIG. 6 illustrates a fragmentary cross-sectional view along line B-B′ in FIGS. 1, 2, 3, or 4, according to one or more aspects of the present disclosure.

FIG. 7 illustrates a fragmentary cross-sectional view along line C-C′ in FIGS. 1, 2, 3, or 4, according to one or more aspects of the present disclosure.

FIG. 8 illustrates a flow chart of a method for forming a gate isolation feature in a CFET structure, according to one or more aspects of the present disclosure.

FIGS. 10-15 illustrate fragmentary cross-sectional views of a precursor undergoing various fabrication processes in the method of FIG. 8, according to one or more aspects of the present disclosure.

FIG. 16 is a schematic diagram showing oxygen blocking benefits of a gate isolation feature according to one or more aspects of the present disclosure.

FIG. 17 is a schematic diagram showing threshold voltage benefits of a gate isolation feature according to one or more aspects of the present disclosure.

FIG. 18 illustrates a flow chart of a method for forming different gate isolation features in different device regions, according to one or more aspects of the present disclosure.

FIGS. 19-26 illustrate fragmentary cross-sectional views of a precursor undergoing various fabrication processes in the method of FIG. 18, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be referred to as a complementary field effect transistor (CFET). The multi-gate devices in a CFET may be FinFETs or GAA transistors. The gate structure for the top multi-gate device and the second multi-gate device may be electrically coupled together or insulated from one another depending on the design. During manufacturing of CFETs over a substrate, gate stacks may be formed to span over multiple active regions and a gate cut process may be performed to divide the gate stacks into multiple segments by gate isolation features. Because each of the gate isolation features are disposed between two gate segments, the industry has devoted efforts to reduce or minimize an effective dielectric constant of the gate isolation features. The goal for those efforts is to reduce parasitic capacitance between gate segments and increase device speed.

The reduction of the dielectric constant of gate isolation features is not without consequence across the board. Low-dielectric-constant (low-k) dielectric materials in gate isolation features tend to include oxygen and can become a source of oxygen in gate oxidation processes. When metals in gate structures oxidizes, the threshold voltage of the device may deviate from the design value. Logic devices are less sensitive to threshold voltage degradation as long as they still switch with appropriate response time. The same cannot be said for memory devices, such as static random access memory (SRAM) devices. When there is uneven oxidation of components in gate structures at different locations in an SRAM array, the minimum supply voltage (Vmin) across the SRAM array may increase and some SRAM cells may stop operating properly. There is a need to contain oxygen diffusion from gate isolation features, at least for the memory devices.

The present disclosure provides multiple methods of forming gate isolation features to reduce gate oxidation of devices in a memory structure. A method according to one embodiment forms a gate isolation trench into gate structures of CFET structures in both logic device regions and memory device regions. A nitrogen-containing layer is deposited into the gate isolation trench. A liner is deposited over the nitrogen containing layer. An oxygen-containing dielectric layer is deposited over the liner. A planarization process is performed to form a gate isolation feature in the gate isolation trench. The liner helps reduce or control oxygen diffusion into the gate structures. A method according to another embodiment forms a first gate isolation trench into gate structures of CFET structures in a logic device region and a second gate isolation trench into gate structures of CFET structures in memory device region. A nitrogen-containing dielectric layer is deposited to fill the first gate isolation trench and the second gate isolation trench. With the memory device region covered, an inner trench is formed in the nitrogen-containing dielectric layer in the first gate isolation trench. An oxygen-containing dielectric layer is then deposited into the inner trench. A planarization process is then performed to form a first gate isolation feature in the logic device region and a second gate isolation feature in the memory device region. The first gate isolation feature is configured to provide fast switching speed for the logic devices and the second gate isolation feature is configured to minimize oxygen diffusion into the gate structures of the memory devices.

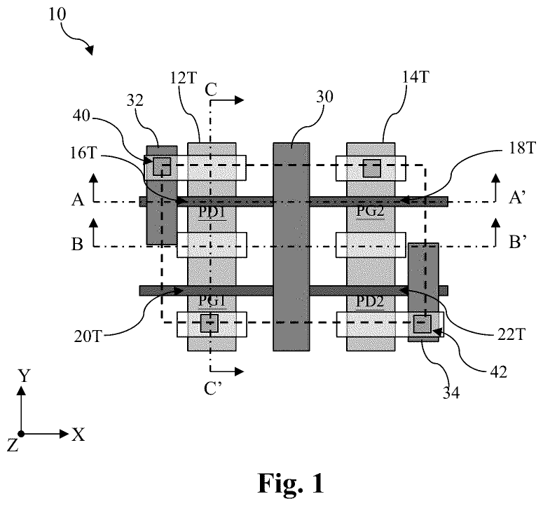

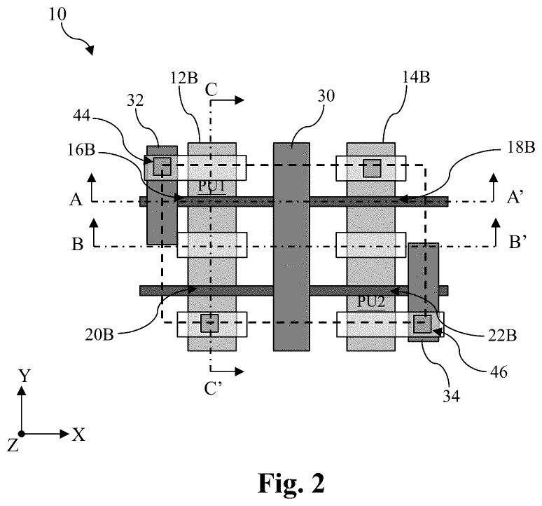

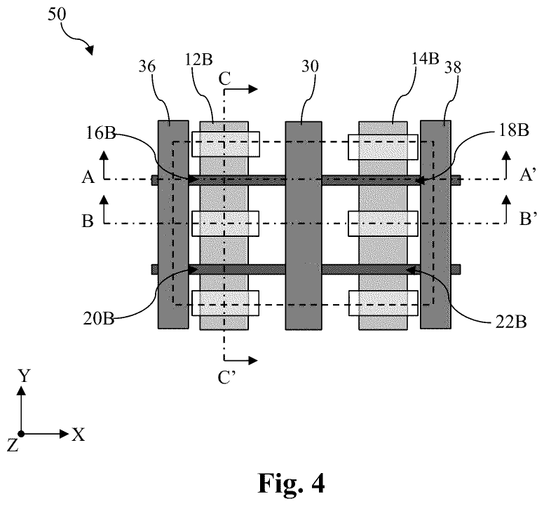

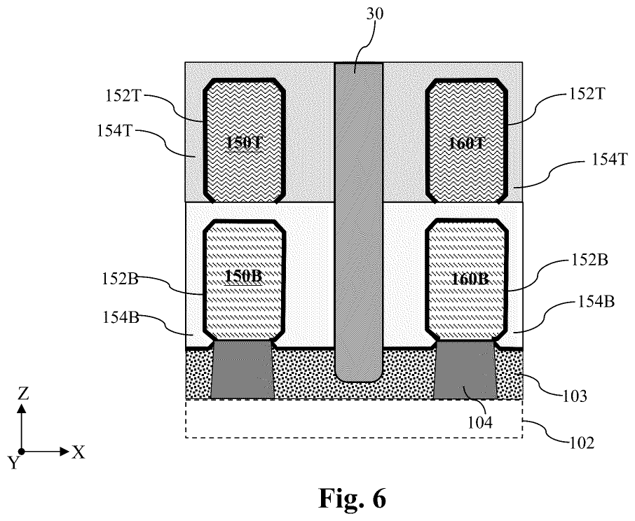

Gate isolation features may be implemented in CFET structures for both logic devices and memory devices. FIGS. 1 and 2 illustrate layouts of a 6-transistor (6T) static random access memory (SRAM) cell 10 having a CFET construction. FIG. 1 illustrates a layout of a top device layer of the SRAM cell 10 and FIG. 2 illustrates a layout of a bottom device layer of the SRAM cell 10. Referring to FIG. 1, in the top device layer, the SRAM cell 10 includes a first top active region 12T and a second top active region 14T extending lengthwise parallelly along the Y direction. As will be illustrated in fragmentary cross-sectional views in FIGS. 4 and 6, each of the first top active region 12T and the second top active region 14T includes multiple channel structures or nanostructures also extending lengthwise along the Y direction. A first top gate structure 16T engages the first top active region 12T to form a first pull-down transistor (PD1). A second top gate structure 18T engages the second top active region 14T to form a second pass-gate transistor (PG2). A third top gate structure 20T engages the first top active region 12T to form a first pass-gate transistor (PG1). A fourth top gate structure 22T engages the second top active region 14T to form a second pull-down transistor (PD2). The first top gate structure 16T and the second top gate structure 18T extend lengthwise along the X direction and are aligned along the X direction. The third top gate structure 20T and the fourth top gate structure 22T extend lengthwise along the X direction and are aligned along the X direction. A first gate isolation feature 30 extends lengthwise along the Y direction to be disposed between the first top gate structure 16T and the second top gate structure 18T as well as between the third top gate structure 20T and the fourth top gate structure 22T. A drain of the first pull-down transistor (PD1) and a drain of the second pull-down transistor (PD2) are coupled to a ground voltage (Vss) by way of a first contact via 40 and a second contact via 42. A second gate isolation feature 32 cuts short the first top gate structure 16T. A third gate isolation feature 34 cuts short the fourth top gate structure 22T.

Referring to FIG. 2, in the bottom device layer, the SRAM cell 10 includes a first bottom active region 12B and a second bottom active region 14B extending lengthwise parallelly along the Y direction. As will be illustrated in fragmentary cross-sectional views in FIGS. 4 and 6, each of the first bottom active region 12B and the second bottom active region 14B includes multiple channel structures or nanostructures also extending lengthwise along the Y direction. A first bottom gate structure 16B engages the first bottom active region 12B to form a first pull-up transistor (PU1). A second bottom gate structure 18B engages the second bottom active region 14B and is electrically floating. A third top gate structure 20T engages the first bottom active region 12B and is electrically floating. A fourth bottom gate structure 22B engages the second bottom active region 14B to form a second pull-up transistor (PU2). The first bottom gate structure 16B and the second bottom gate structure 18B extend lengthwise along the X direction and are aligned along the X direction. The third bottom gate structure 20B and the fourth bottom gate structure 22B extend lengthwise along the X direction and are aligned along the X direction. A first gate isolation feature 30 extends lengthwise along the Y direction to be disposed between the first bottom gate structure 16B and the second bottom gate structure 18B as well as between the third bottom gate structure 20B and the fourth bottom gate structure 22B. A source of the first pull-up transistor (PU1) and a source of the second pull-up transistor (PU2) are coupled to a supply voltage (Vdd) by way of a third contact via 44 and a fourth contact via 46. The second gate isolation feature 32 cuts short the first bottom gate structure 16B. The third gate isolation feature 34 cuts short the fourth bottom gate structure 22B. It can be seen that the first gate isolation feature 30, the second gate isolation feature 32 and the third gate isolation feature 34 extend through the top device layer and the bottom device layer.

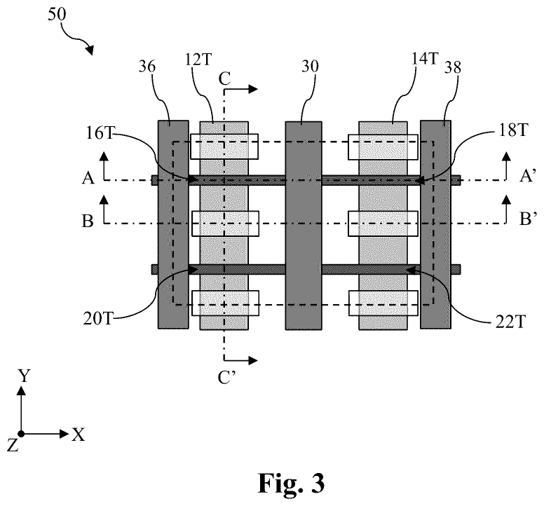

FIGS. 3 and 4 illustrate layouts of a logic standard cell 50 having a CFET construction. FIG. 3 illustrates a layout of a top device layer of the logic standard cell 50. As illustrated in FIG. 3, in the top device layer, the logic standard cell 50 includes a first top active region 12T and a second top active region 14T extending lengthwise parallelly along the Y direction. As will be illustrated in fragmentary cross-sectional views in FIGS. 4 and 6, each of the first top active region 12T and the second top active region 14T includes multiple channel structures or nanostructures also extending lengthwise along the Y direction. A first top gate structure 16T engages the first top active region 12T. A second top gate structure 18T engages the second top active region 14T. A third top gate structure 20T engages the first top active region 12T. A fourth top gate structure 22T engages the second top active region 14T. The first top gate structure 16T and the second top gate structure 18T extend lengthwise along the X direction and are aligned along the X direction. The third top gate structure 20T and the fourth top gate structure 22T extend lengthwise along the X direction and are aligned along the X direction. A first gate isolation feature 30 extends lengthwise along the Y direction to be disposed between the first top gate structure 16T and the second top gate structure 18T as well as between the third top gate structure 20T and the fourth top gate structure 22T. A fourth gate isolation feature 36 cuts short the first top gate structure 16T and the third top gate structure 20T. A fifth gate isolation feature 38 cuts short the second top gate structure 18T and the fourth top gate structure 22T.

As illustrated in FIG. 4, in the bottom device layer, the logic standard cell 50 includes a first bottom active region 12B and a second bottom active region 14B extending lengthwise parallelly along the Y direction. As will be illustrated in fragmentary cross-sectional views in FIGS. 4 and 6, each of the first bottom active region 12B and the second bottom active region 14B includes multiple channel structures or nanostructures also extending lengthwise along the Y direction. A first bottom gate structure 16B engages the first bottom active region 12B. A second bottom gate structure 18B engages the second bottom active region 14B. A third bottom gate structure 20B engages the first bottom active region 12B. A fourth bottom gate structure 22B engages the second bottom active region 12B. The first bottom gate structure 16B and the second bottom gate structure 18B extend lengthwise along the X direction and are aligned along the X direction. The third bottom gate structure 20B and the fourth bottom gate structure 22B extend lengthwise along the X direction and are aligned along the X direction. The first gate isolation feature 30 extends lengthwise along the Y direction to be disposed between the first bottom gate structure 16B and the second bottom gate structure 18B as well as between the third bottom gate structure 20B and the fourth bottom gate structure 22B. The fourth gate isolation feature 36 cuts short the first bottom gate structure 16B and the third bottom gate structure 20B. The fifth gate isolation feature 38 cuts short the second bottom gate structure 18B and the fourth bottom gate structure 22B.

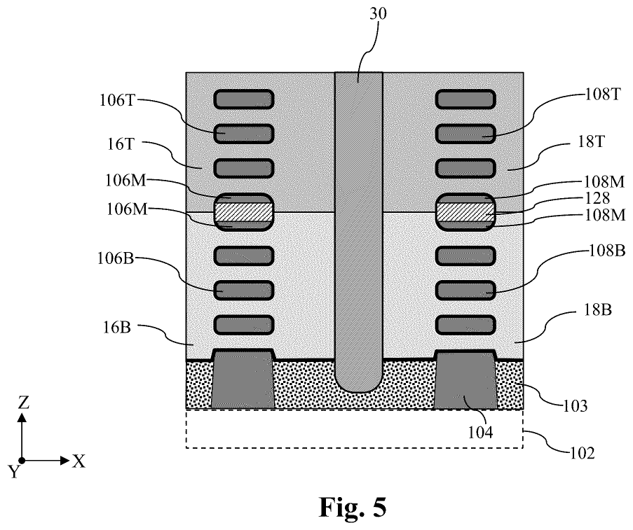

It can be seen that the SRAM cell 10 and the logic standard cell 50 share similarities with respect to the first gate isolation feature 30, the first top active region 12T, the second top active region 14T, the first bottom active region 12B, the second bottom active region 14B, the first top gate structure 16T, the second top gate structure 18T, the third top gate structure 20T, the fourth top gate structure 22T, the first bottom gate structure 16B, the second bottom gate structure 18B, the third bottom gate structure 20B, and the fourth bottom gate structure 22B. FIGS. 5, 6 and 7 illustrates fragmentary cross-sectional views along line A-A′ along the X direction, line B-B′ along the X direction, and line C-C′ along the Y direction.

FIG. 5 illustrates a fragmentary cross-sectional view along line A-A in FIGS. 1, 2, 3, or 4. The first bottom active region 12B includes a first bottom channel structures 106B stacked one over another over a base fin 104. The first top active region 12T includes a first top channel structures 106T stacked one over another over the first bottom channel structures 106B. The first bottom gate structure 16B wraps around each of the first bottom channel structures 106B. The first top gate structure 16T wraps around each of the first top channel structures 106T. The second top gate structure 18T wraps around each of the second top channel structures 108T. The second bottom gate structure 18B wraps around each of the second bottom channel structures 108B. The base fins 104 are patterned from a substrate 102, which is omitted in subsequent drawings for brevity. An isolation feature 103 is deposited over the substrate 102 and extends between sidewalls of the base fins 104. The first gate isolation feature 30 extends between the first bottom gate structure 16B and the second bottom gate structure 18B and between the first top gate structure 16T and the second top gate structure 18T. In some embodiments, the first gate isolation feature 30 partially extends into the isolation feature 103 and between the base fins 104. An insulation layer 128 is disposed between the first bottom channel structures 106B and the first top channel structures 106T. In some embodiments, the insulation layer 128 is vertically sandwiched between two middle semiconductor layers 106M. In some implementations, the first bottom gate structure 16B and the second bottom gate structure 18B are p-type gate structures and include p-type work function metal (p-WFM) layer and the first top gate structure 16T and the second top gate structure 18T are n-type gate structures and include n-type work function metal (n-WFM) layer.

FIG. 6 illustrates a fragmentary cross-sectional view along line B-B′ in FIGS. 1, 2, 3, or 4. Sidewalls of the first bottom channel structures 106B contact a first bottom source/drain feature 150B. Sidewalls of the second bottom channel structures 108B contact a second bottom source/drain feature 160B. Sidewalls of the first top channel structures 106T contact a first top source/drain feature 150T. Sidewalls of the second top channel structures 108B contact a second top source/drain feature 160T. A bottom contact etch stop layer (CESL) 152B is disposed over the isolation feature 103, surfaces of the first bottom source/drain feature 150B, surfaces of the second bottom source/drain feature 160B. A bottom interlayer dielectric (ILD) layer 154B is disposed over the bottom CESL 152B. A top CESL 152T is disposed over surfaces of the first top source/drain feature 150T and surfaces of the second top source/drain feature 160T. A top ILD layer 154T is disposed over the top CESL 152T.

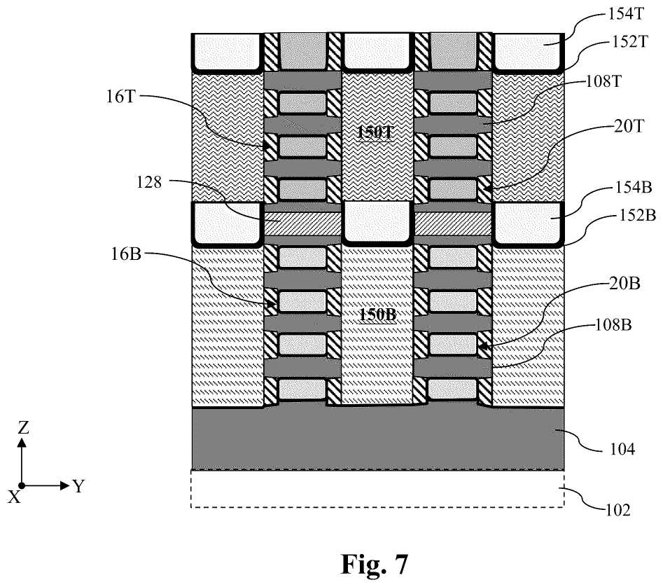

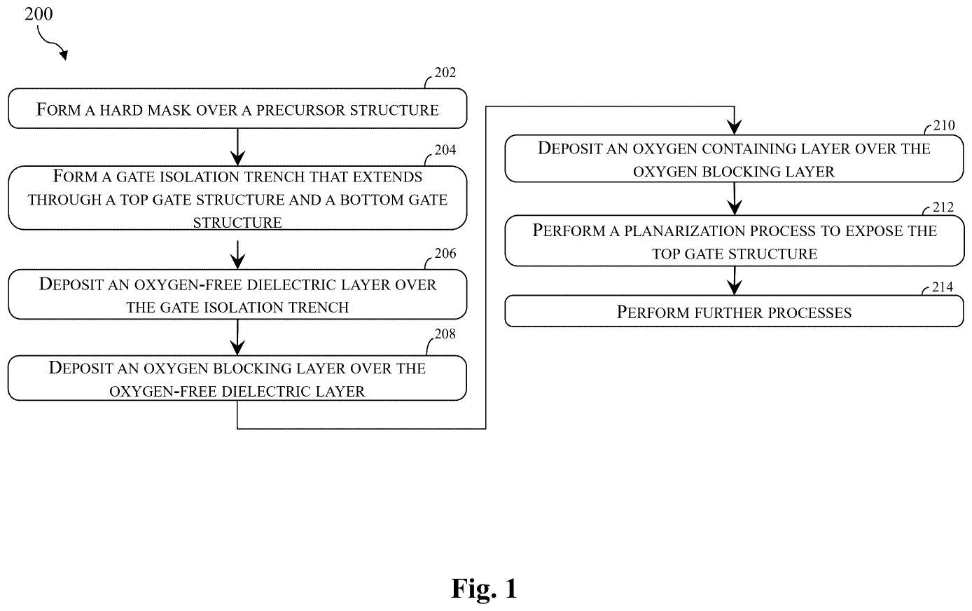

FIG. 7 illustrates a fragmentary cross-sectional view along line C-C′ in FIGS. 1, 2, 3, or 4. As shown in FIG. 7, the first bottom channel structures 106B are sandwiched between two first bottom source/drain features 150B; the first top channel structures 106T are sandwiched between two first top source/drain features 150T. Similarly, while not explicitly shown in any cross-sectional views, the second bottom channel structures 108B are sandwiched between two second bottom source/drain features 160B; the second top channel structures 108T are sandwiched between two first top source/drain features 160T.

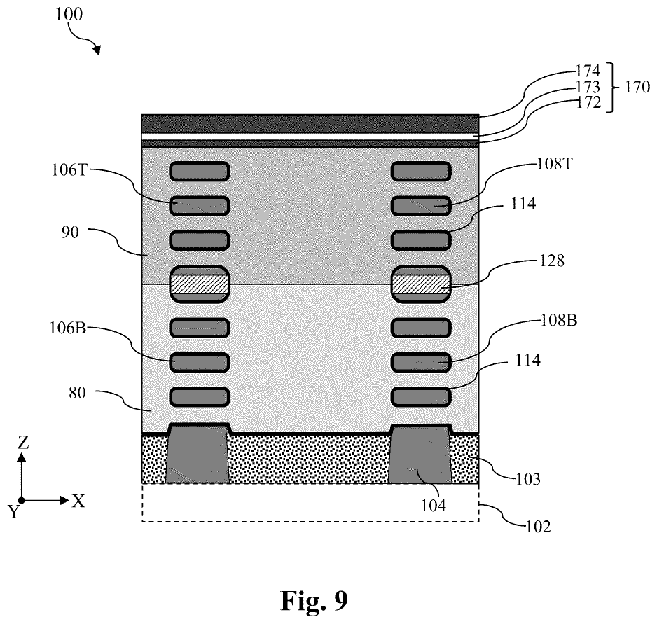

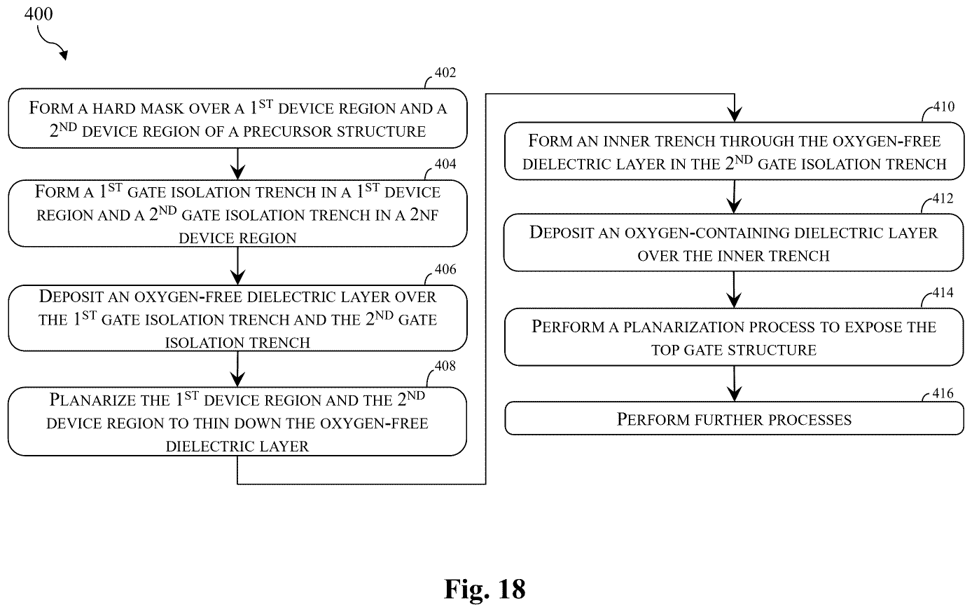

Methods to be described below, such as method 200 in FIG. 8 and method 400 in FIG. 18, include operations to form different gate isolation features in place of the first gate isolation feature 30 shown in FIGS. 1-6. That is, FIGS. 1-7 provides details of structures around the gate isolation feature to be formed using method 200 or method 400.

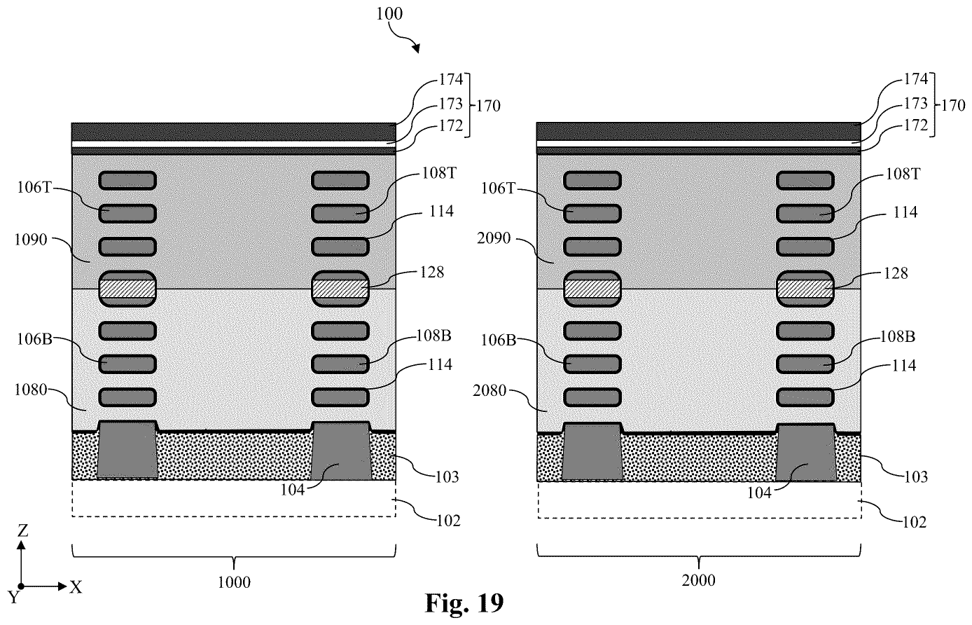

FIGS. 8 and 18 are flowcharts illustrating method 200 and method 400 for forming gate isolation features to CFET structures in logic device regions and memory device regions, according to various aspects of the present disclosure. Methods 200 and 400 are merely examples and are not intended to limit the present disclosure to what is explicitly illustrated in methods 200 and 400. Additional steps may be provided before, during and after method 200 and 400, and some steps described can be replaced, eliminated, or moved around for additional embodiments of the method. Not all steps are described herein in detail for reasons of simplicity. Method 200 is described below in conjunction with FIGS. 9-15, which are fragmentary cross-sectional views of a precursor structure 100 at different stages of fabrication according to embodiments of method 200. Method 400 is described below in conjunction with FIGS. 19-26, which are fragmentary cross-sectional views of a precursor structure 100 at different stages of fabrication according to embodiments of method 400. Because the precursor structure 100 will be fabricated into a semiconductor device 100 upon conclusion of the fabrication processes, the precursor structure 100 may be referred to as the semiconductor device 100 as the context requires. Additionally, throughout the present application and across different embodiments, like reference numerals denote like features with similar structures and compositions, unless otherwise excepted. Source/drain region(s) may refer to a source or a drain, individually or collectively dependent upon the context.

Method 200 forms a same type of gate isolation features in both logic device regions and memory device regions.

Referring to FIGS. 8 and 9, method 200 includes a block 202 where a hard mask layer 170 is formed over a precursor structure 100. The precursor structure 100 includes a substrate 102 (shown in dotted lines and will be omitted in subsequent figures), base fins 104 formed from the substrate 102, an isolation feature 103 over the substrate 102 and disposed among base fins 104, first bottom channel structures 106B, second bottom channel structures 108B, first top channel structures 106T, second top channel structures 108T, a bottom gates structure 80 wrapping around the first bottom channel structures 106B and the second bottom channel structures 108B, a top gate structure 90 wrapping around the first top channel structures 106T and the second top channel structures 108T.

In one embodiment, the substrate 102 may be a silicon (Si) substrate. In some other embodiments, the substrate 102 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 102 may also include an insulating layer, such as a silicon oxide layer, to have a silicon-on-insulator (SOI) structure. The base fins 104 are formed from the substrate 102 and may share the same composition of the substrate 102. In one embodiment, the base fins 204 may include silicon (Si). The isolation feature 103 may also be referred to as a shallow trench isolation (STI) feature 103. The isolation feature 103 may include silicon oxide, silicon oxynitride, fluorine-doped silicate glass (FSG), a low-k dielectric, combinations thereof, and/or other suitable materials.

The first bottom channel structures 106B, the second bottom channel structure 108B, the first top channel structures 106T, and the second top channel structures 108T are formed from a stack of epitaxial layers formed on the substrate 102. In an example process, the stack of epitaxial layers includes a plurality silicon layers interleaved by a plurality of silicon germanium layers. After the stack is patterned to form fin-like structures, a dummy gate stack is formed over the fin-like structure. After formation of source/drain features, the dummy gate stack is selectively removed and the plurality of silicon germanium layers are selectively removed to release the first bottom channel structures 106B, the second bottom channel structure 108B, the first top channel structures 106T, and the second top channel structures 108T. In some embodiments, the first bottom channel structures 106B, the second bottom channel structure 108B, the first top channel structures 106T, and the second top channel structures 108T may include silicon (Si). The bottom gate structure 80 is deposited to wrap around each of the first bottom channel structures 106B and the second bottom channel structure 108B. The top gate structure 90 is deposited to wrap around each of the first top channel structures 106T and the second top channel structures 108T. The precursor structure 100 further includes two middle semiconductor layers 108M. An insulator layer 128 is vertically disposed between the two middle semiconductor layers 108M. The insulator layer 128 may include silicon oxide, silicon nitride, silicon oxycarbonitride to separate the bottom channel structures from the top channel structures.

The bottom gate structure 80 includes an interfacial layer interfacing the first bottom channel structures 106B and the second bottom channel structure 108B, a gate dielectric layer 114 over the interfacial layer, and a bottom gate electrode over the gate dielectric layer 114. In some embodiments, the interfacial layer may include silicon oxide or hafnium silicate. The gate dielectric layer 114 is formed of high-K dielectric materials. As used and described herein, high-k dielectric materials include dielectric materials having a high dielectric constant, for example, greater than that of thermal silicon oxide (~3.9). In one embodiment, the gate dielectric layer 114 may include hafnium oxide. Alternatively, the gate dielectric layer 114 may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba, Sr)TiO₃ (BST), silicon nitride (SiN), silicon oxynitride (SiON), combinations thereof, or other suitable material. In the depicted embodiments, the bottom gate structure 80 is a p-type gate structure and the bottom gate electrode includes at least one p-type work function metal layers. In some instances, the p-type work function metal layers may include titanium nitride (TiN), tantalum nitride (TaN), ruthenium (Ru), molybdenum (Mo), tungsten (W), or platinum (Pt).

The top gate structure 90 includes an interfacial layer interfacing the first top channel structures 106T and the second top channel structure 108T, the gate dielectric layer 114 over the interfacial layer, and a top gate electrode over the gate dielectric layer 114. In the depicted embodiments, the top gate structure 90 is an n-type gate structure and the top gate electrode includes at least one n-type work function metal layers. In some instances, the n-type work function metal layers may include titanium (Ti), aluminum (Al), tantalum carbide (TiC), tantalum carbide nitride (TiCN), titanium aluminum (TiAl), titanium aluminum carbide (TiAlC), or tantalum silicon nitride (TiSiN). When the n-type work function metal layers include aluminum, they become more susceptible to oxidation due to oxygen diffusion from adjacent structures, such as the gate isolation features.

A block 202, the hard mask layer 170 is deposited over the precursor 100, such as over a top surface of the top gate structure 90. The hard mask layer 170 may be a single layer or a multilayer. In the depicted embodiments, the hard mask layer 170 includes a first layer 172, a second layer 173 over the first layer 172, and a third layer 174 over the second layer 173. In some embodiments, the first layer 172 and the third layer 174 may share the same composition while the second layer 173 has a composition different from that of the first layer 172 or the third layer 174. To prevent oxygen diffusion into the top gate structure 90, the first layer 172, the second layer 173, and the third layer 174 are free of oxygen. In some embodiments, the first layer 172 and the third layer 174 includes silicon nitride or silicon carbonitride and the second layer includes silicon. In one embodiment, the first layer 172 and the third layer 174 includes silicon nitride and the second layer includes silicon. In some implementations, the hard mask layer 170 is deposited using chemical vapor deposition (CVD) or atomic layer deposition (ALD).

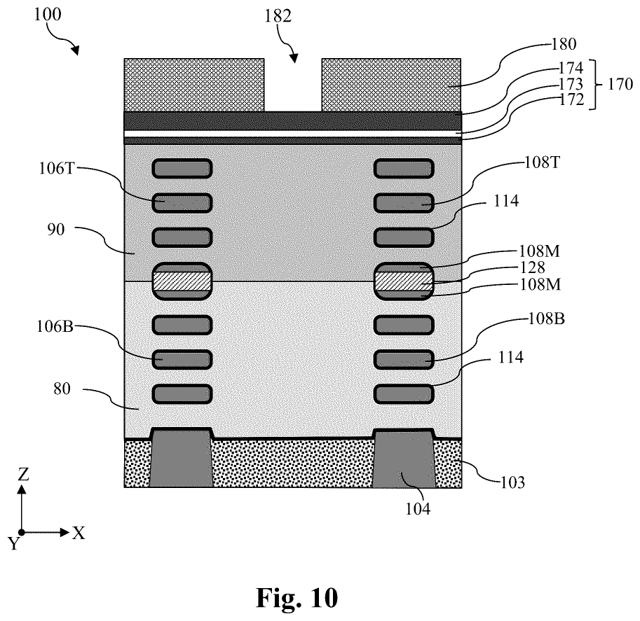

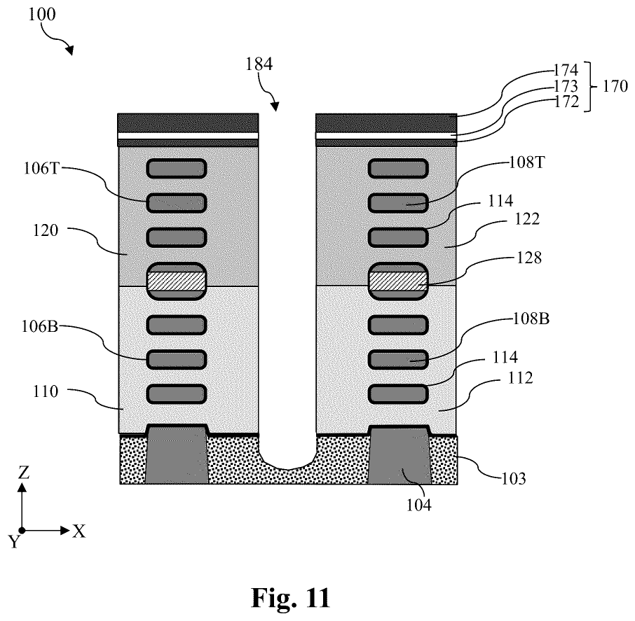

Referring to FIGS. 8, 10 and 11, method 200 includes a block 204 where a gate isolation trench 184 through a top gate structure 90 and a bottom gate structure 80. Operations at block 204 may include formation of a first patterned photoresist layer 180 (shown in FIG. 10) and etching of the precursor structure 100 using the first patterned photoresist layer 180 as an etch mask (shown in FIG. 11). Referring to FIG. 10, the first photoresist layer 180 is deposited over the hard mask layer 170 using spin-on coating. At block 204, the first photoresist layer 180 is patterned by undergoes soft baking, mask aligning, exposure, post-exposure baking, photoresist developing, rinsing, drying (e.g., spin-drying and/or hard baking), other suitable lithography techniques, and/or combinations thereof. The first patterned photoresist layer 180 includes a mask opening 182. An etching process, such as a dry etching (e.g., RIE etching), a wet etching, or a combination thereof, is performed to etch the hard mask layer 170, the top gate structure 90, the bottom gate structure 80, and the isolation feature 103. Referring to FIG. 11, the etching at block 204 may form a gate isolation trench 184 that extends vertically through the hard mask layer 170, divides the top gate structure 90 into a first top gate structure 120 and a second top gate structure 122, divides the bottom gate structure 80 into a first bottom gate structure 110 and a second bottom gate structure 112. In some embodiments illustrated in FIG. 11, in order to ensure complete severance of the bottom gate structure 80, the gate isolation trench 184 at least partially extends into the isolation feature 103. As shown in FIG. 11, sidewalls of the hard mask layer 170, sidewalls of the first top gate structure 120 and the second top gate structure 122, sidewalls of the first bottom gate structure 110 and the second bottom gate structure 112, sidewalls of the isolation feature 103, and a top surface of the isolation feature 103 are exposed in the gate isolation trench 184. After formation of the gate isolation trench 184, any remaining first patterned photoresist layer 180 is removed from the precursor structure 100. In some instances, the gate isolation trench 184 may also be referred to as a gate cut trench.

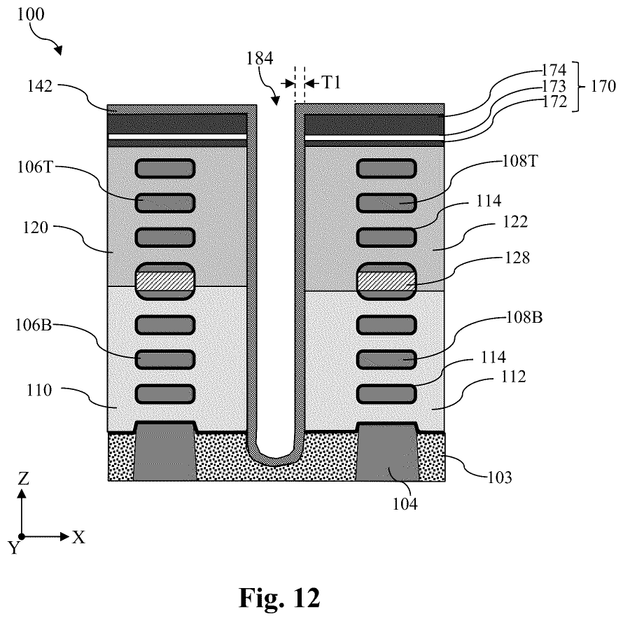

Referring to FIGS. 8 and 12, method 200 includes a block 206 where an oxygen-free dielectric layer 142 is deposited over the gate isolation trench 184. In some embodiments, the oxygen-free dielectric layer 142 may include silicon nitride and may be deposited using CVD or ALD. As shown in FIG. 12, the deposited oxygen-free dielectric layer 142 may be conformally deposited over the gate isolation trench 184 to interface sidewalls of the hard mask layer 170, sidewalls of the first top gate structure 120 and the second top gate structure 122, sidewalls of the first bottom gate structure 110 and the second bottom gate structure 112, sidewalls of the isolation feature 103, and the top surface of the isolation feature 103. The oxygen-free dielectric layer 142 may have a first thickness (T1) of between about 3 nm and about 4 nm.

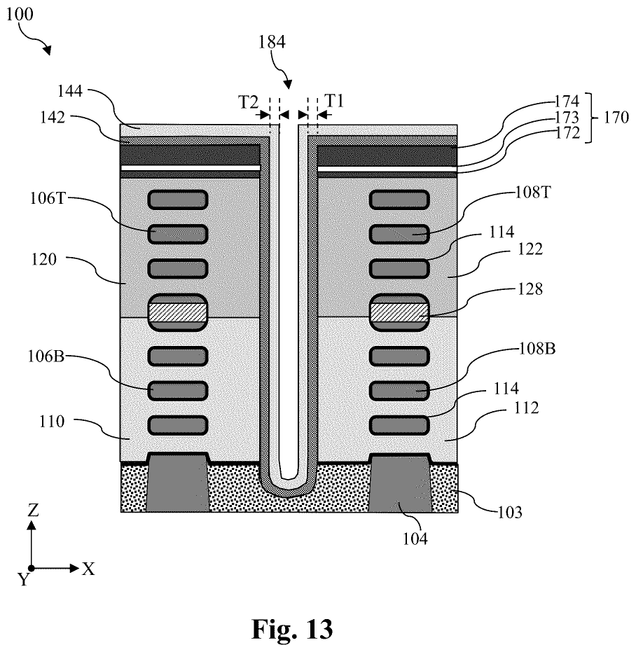

Referring to FIGS. 8 and 13, method 200 includes a block 208 where an oxygen blocking layer 144 is deposited over the gate isolation trench 184. The oxygen blocking layer 144 may “block” oxygen diffusion using more than one mechanism. For example, the oxygen blocking layer 144 may be a sacrificial layer to consume and trap oxygen while itself is oxidized. In this example, the oxygen blocking layer 144 may include amorphous silicon, silicon carbonitride, or amorphous carbon. For another example, the oxygen blocking layer 144 may be a dense oxygen barrier that reduces or limits oxygen diffusion. In this example, the oxygen blocking layer 144 may include polymers, such as polyimide. In one embodiment, the oxygen blocking layer 144 may include amorphous silicon. The oxygen blocking layer 144 may be referred to as a liner and has a second thickness T2 smaller than the first thickness T1. In some instances, the second thickness T2 may be between about 1 nm and about 1.5 nm. A ratio of the second thickness T2 to the first thickness T1 may be between about 1:4 and about 1:2. The oxygen blocking layer 144 may be deposited using ALD or plasma-enhanced ALD (PEALD). While not explicitly shown in the figures, the oxygen blocking layer 144 may be a multilayer. In one example, the oxygen blocking layer 144 may include silicon sublayer interfacing the oxygen-free dielectric layer 142 and a silicon carbonitride sublayer interfacing the to-be-deposited oxygen-containing dielectric layer. It should be noted that the addition layer interfaces due to the introduction of the oxygen blocking layer 144 also helps slow down the diffusion of oxygen. For example, without the oxygen blocking layer 144, the oxygen-free dielectric layer 142 directly interfaces the oxygen-containing dielectric layer 146 (to be described below). With the introduction of the oxygen blocking layer 144, the oxygen-free dielectric layer 142 interfaces the oxygen blocking layer 144 and the oxygen blocking layer 144 interfaces the oxygen-containing dielectric layer 146. The additional interface creates barrier for the diffusion of oxygen from the oxygen-containing dielectric layer 146.

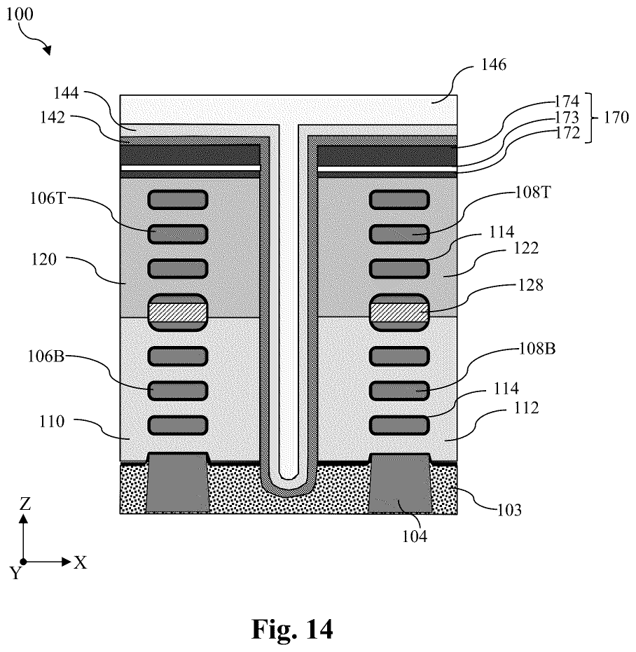

Referring to FIGS. 8 and 14, method 200 includes a block 210 where an oxygen-containing dielectric layer 146 over the oxygen blocking layer 144. In some embodiments, the oxygen-containing dielectric layer 146 may include silicon oxide and may be deposited using flowable CVD (FCVD), spin-on coating, CVD, or ALD. As shown in FIG. 14, at block 210, the oxygen-containing dielectric layer 146 not only completely fills the gate isolation trench 184 but also include a thickness over the top surface of the oxygen blocking layer 144.

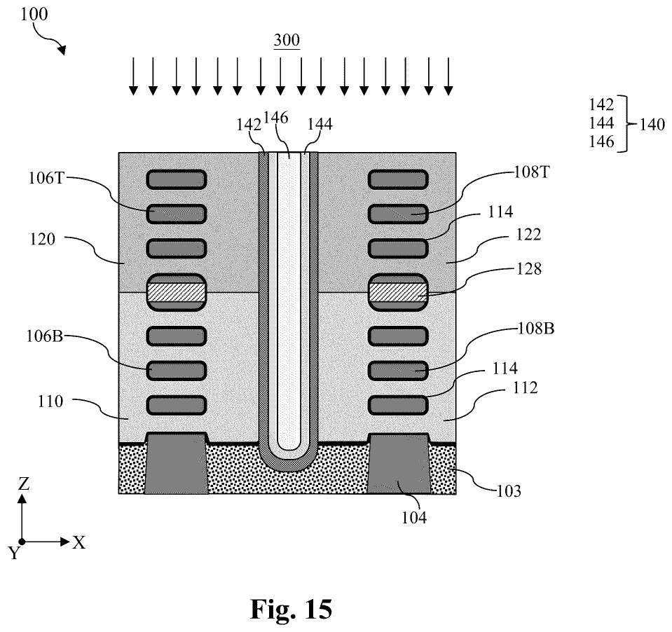

Referring to FIGS. 8 and 15, method 200 includes a block 212 where a planarization process 300 is performed to expose the top gate structures 120 and 122. The planarization process 300 may include a chemical mechanical polishing (CMP) process. At block 212, the planarization process 300 is performed to remove excess of the oxygen-free dielectric layer 142, the oxygen blocking layer 144, and the oxygen containing layer 146 to expose top surfaces of the first top gate structure 120 and the second top gate structure 122. At this stage, a gate isolation feature 140 is substantially formed. As shown in FIG. 15, the gate isolation feature 140 includes the oxygen-free dielectric layer 142 to interface the gate structures (including the first top gate structure 120, the second top gate structure 122, the first bottom gate structure 110, and the second bottom gate structure 112). The gate isolation feature 140 also includes an oxygen blocking layer 144 to shield the oxygen-free dielectric layer 142 from oxygen diffusion from the innermost oxygen-containing dielectric layer 146.

Referring to FIG. 8, method 200 includes a block 214 where further processes are performed. Such further processes may include formation of middle-end-of-line (MEOL) features and formation of back-end-of-line (BEOL) features. MEOL features may include frontside source/drain contacts, gate contact vias, backside source/drain contact via, and backside gate contact vias. BEOL features may include a frontside interconnect structure and a backside interconnect structure. The frontside interconnect structure includes a plurality of dielectric layers and a plurality of metal layers disposed in the plurality of dielectric layers. In some embodiments, the frontside interconnect structure includes between about 8 metal layers and about 20 metal layers. The backside interconnect structure includes a plurality of dielectric layers and a plurality of metal layers disposed in the plurality of dielectric layers. In some embodiments, the backside interconnect structure includes between about 2 metal layers and about 10 metal layers.

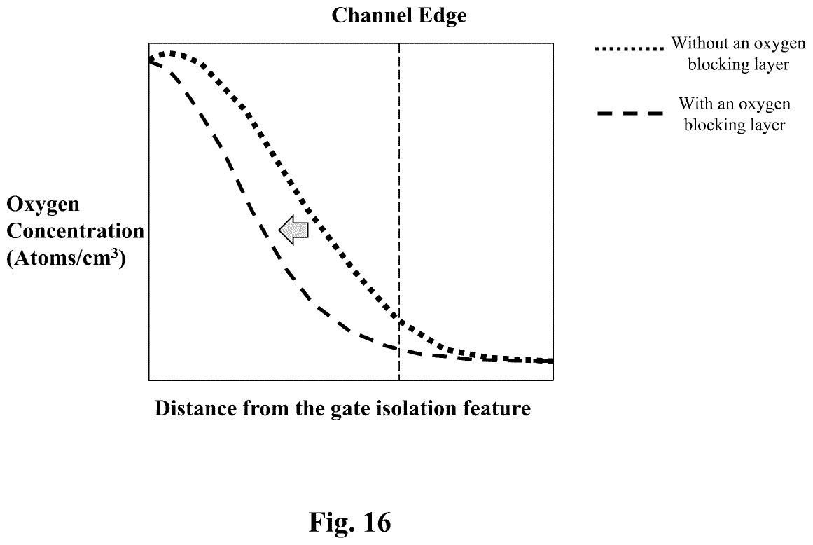

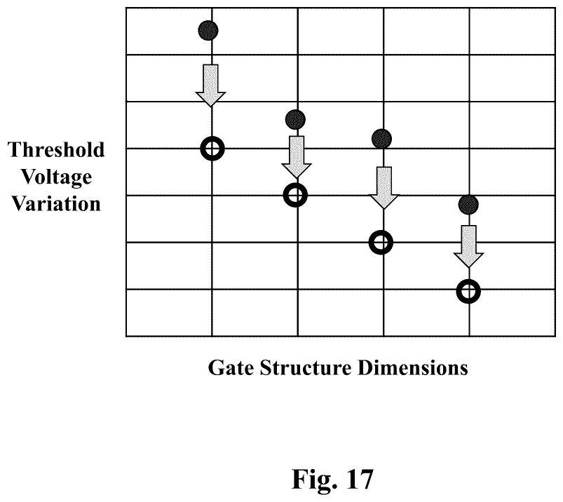

Simulations and experiments have demonstrated the oxygen blocking benefits of the oxygen blocking layer 144. Reference is first made to FIG. 16, which charts oxygen concentration relative to the distance from the gate isolation feature with and without implementation of the oxygen blocking layer 144. The chart in FIG. 16 illustrates that the oxygen concentration distribution recedes toward the gate isolation feature 140. This demonstrates that the oxygen blocking layer 144 slows down oxygen diffusion into the gate structure and toward the channel. FIG. 17 includes a chart showing that implementation of the oxygen blocking layer 144 reduces threshold voltage variation between about 8% and about 10%. As described above, uneven oxidation of gate structures, especially n-type gate structures that include aluminum (Al), the minimum supply voltage (Vmin) across an SRAM array may increase and some SRAM cells may stop operating properly. By reducing threshold voltage variations, the oxygen blocking layer 144, when implemented in SRAM structures, reduces variations or increases of the Vmin.

Method 400 forms different types of gate isolation features in logic device regions and memory device regions.

Referring to FIGS. 18 and 19, method 400 includes a block 402 where a hard mask 170 is formed over a first device region 1000 and a second device region 2000 of a precursor structure 100. The precursor structure 100 shown in FIG. 19 is similar to the precursor structure 100 shown in FIG. 9. Detailed description of the precursor structure 100 in FIG. 19 is omitted for brevity. The precursor structure 100 includes a first device region 1000 and a second device region 2000. In some embodiments, the first device region 1000 is a memory device region that includes the SRAM cells 10 shown in FIGS. 1 and 2 and the second device region 2000 is a logic device region that includes logic standard cells 50 shown in FIGS. 3 and 4. It should be noted that the method 200 is described above without reference to different device regions because similar operations are performed to different device regions, not because that the precursor 100 there does not include multiple device regions.

The precursor structure 100 includes a substrate 102 (shown in dotted lines and will be omitted in subsequent figures), base fins 104 formed from the substrate 102, an isolation feature 103 over the substrate 102 and disposed among base fins 104, first bottom channel structures 106B, second bottom channel structures 108B, first top channel structures 106T, second top channel structures 108T in both the first device region 1000 and the second device region 2000. For ease of describing different arrangements to the gate structures in the two device regions, the reference numerals of the top gate structure and the bottom gate structure in the two device regions are different from those used in FIG. 9. Referring to FIG. 19, over the first device region 1000, a bottom gates structure 1080 wrapping around the first bottom channel structures 106B and the second bottom channel structures 108B and a top gate structure 1090 wrapping around the first top channel structures 106T and the second top channel structures 108T. Over the second device region 2000, a bottom gates structure 2080 wrapping around the first bottom channel structures 106B and the second bottom channel structures 108B and a top gate structure 2090 wrapping around the first top channel structures 106T and the second top channel structures 108T.

A block 402, the hard mask layer 170 is deposited over the first device region 1000 and the second device region 2000, such as over the top surface of the top gate structure 1090 and the top surface of the top gate structure 2090. The hard mask layer 170 may be a single layer or a multilayer. In the depicted embodiments, the hard mask layer 170 includes a first layer 172, a second layer 173 over the first layer 172, and a third layer 174 over the second layer 173. In some embodiments, the first layer 172 and the third layer 174 may share the same composition while the second layer 173 has a composition different from that of the first layer 172 or the third layer 174. To prevent oxygen diffusion into the top gate structure 90, the first layer 172, the second layer 173, and the third layer 174 are free of oxygen. In some embodiments, the first layer 172 and the third layer 174 includes silicon nitride or silicon carbonitride and the second layer includes silicon. In one embodiment, the first layer 172 and the third layer 174 includes silicon nitride and the second layer includes silicon. In some implementations, the hard mask layer 170 is deposited using chemical vapor deposition (CVD) or atomic layer deposition (ALD).

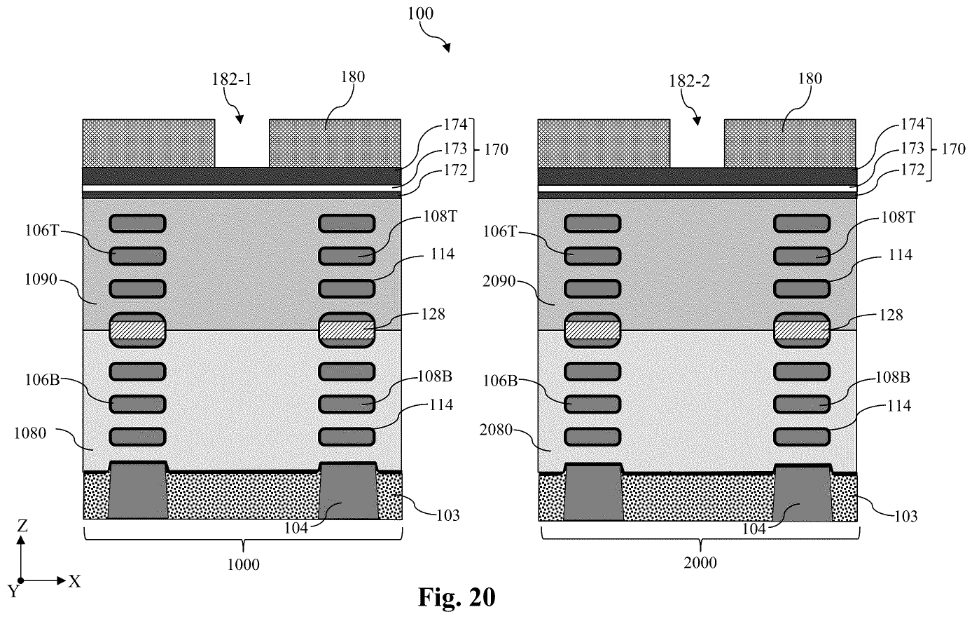

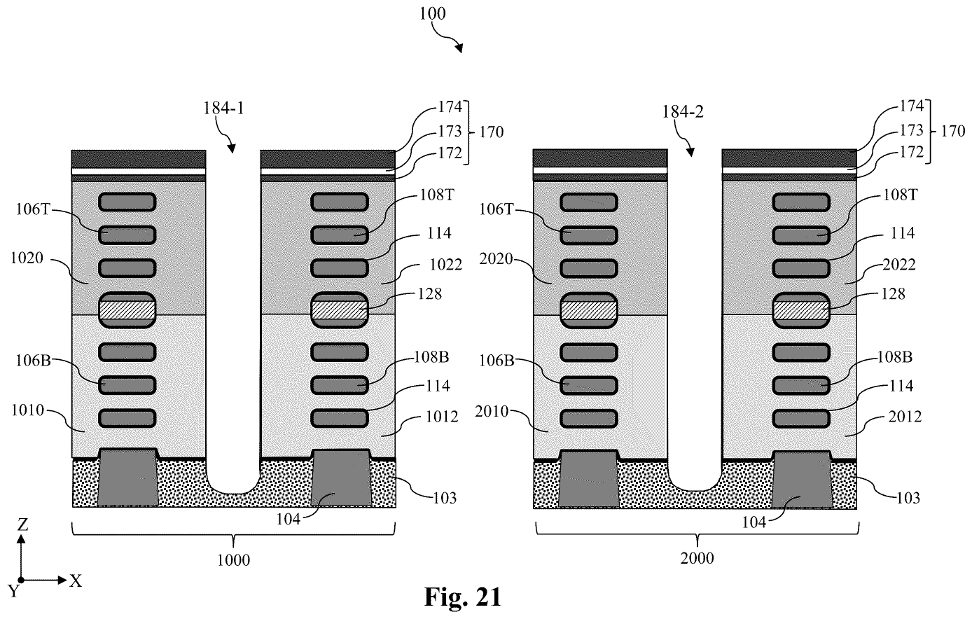

Referring to FIGS. 18, 20 and 21, method 400 includes a block 404 where a first gate isolation trench 184-1 is formed in the first device region 1000 and a second gate isolation trench 184-2 is formed in the second device region 2000. Operations at block 204 may include formation of a first patterned photoresist layer 180 (shown in FIG. 20) and etching of the precursor structure 100 using the first patterned photoresist layer 180 as an etch mask (shown in FIG. 21). Referring to FIG. 20, the first photoresist layer 180 is deposited over the hard mask layer 170 using spin-on coating. At block 404, the first photoresist layer 180 is patterned by undergoes soft baking, mask aligning, exposure, post-exposure baking, photoresist developing, rinsing, drying (e.g., spin-drying and/or hard baking), other suitable lithography techniques, and/or combinations thereof. The first patterned photoresist layer 180 includes a first mask opening 182-1 over the first device region 1000 and a second mask opening 182-2 over the second device region 2000. An etching process, such as a dry etching (e.g., RIE etching), a wet etching, or a combination thereof, is performed to etch the hard mask layer 170, the top gate structures 1090 and 2090, the bottom gate structures 1080 and 2080, and the isolation feature 103. Referring to FIG. 21, the etching at block 404 may form, in the first device region 1000, a first gate isolation trench 184-1 that extends vertically through the hard mask layer 170, divides the top gate structure 1090 into a first top gate structure 1020 and a second top gate structure 1022, divides the bottom gate structure 1080 into a first bottom gate structure 1010 and a second bottom gate structure 1012. The etching at block 404 may also form, in the second device region 2000, a first gate isolation trench 184-2 that extends vertically through the hard mask layer 170, divides the top gate structure 2090 into a first top gate structure 2020 and a second top gate structure 2022, divides the bottom gate structure 2080 into a first bottom gate structure 2010 and a second bottom gate structure 2012. In some embodiments illustrated in FIG. 21, in order to ensure complete severance of the bottom gate structures 1080 or 2080, the gate isolation trenches 184-1 and 184-2 at least partially extends into the isolation feature 103. As shown in FIG. 21, sidewalls of the hard mask layer 170, sidewalls of the first top gate structures 1020 and the second top gate structure 1022, sidewalls of the first bottom gate structure 1010 and the second bottom gate structure 1012, sidewalls of the isolation feature 103, and a top surface of the isolation feature 103 are exposed in the first gate isolation trench 184-1. In the second device region 2000, sidewalls of the hard mask layer 170, sidewalls of the first top gate structures 2020 and the second top gate structure 2022, sidewalls of the first bottom gate structure 2010 and the second bottom gate structure 2012, sidewalls of the isolation feature 103, and a top surface of the isolation feature 103 are exposed in the second gate isolation trench 184-2. After formation of the first gate isolation trench 184-1 and the second gate isolation trench 184-2, any remaining first patterned photoresist layer 180 is removed from the precursor structure 100. In some instances, the first gate isolation trench 184-1 and the second gate isolation trench 184-2 may also be referred to as a first gate cut trench 184-1 and the second gate cut trench 184-2.

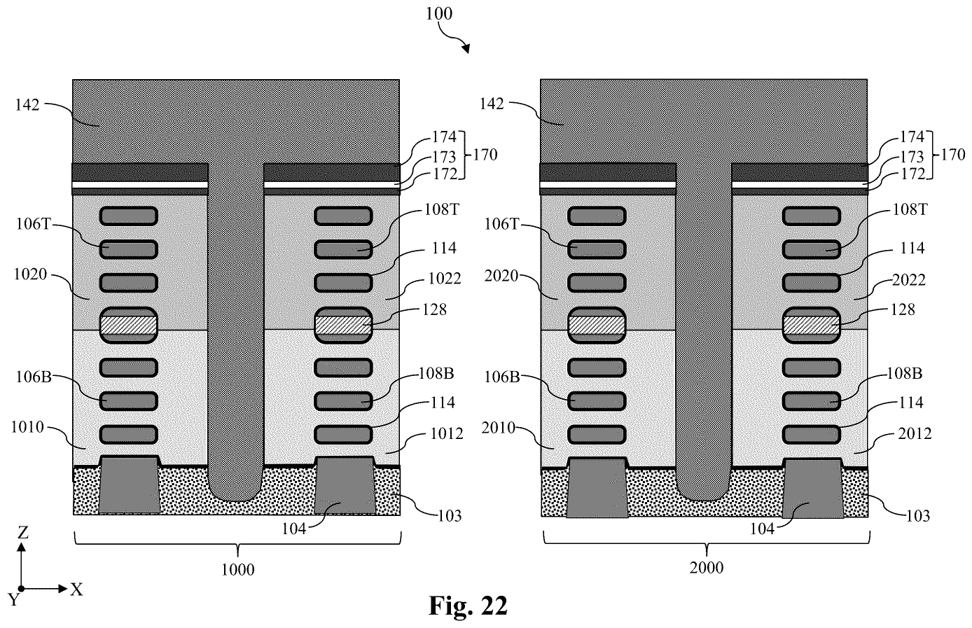

Referring to FIGS. 18 and 22, method 400 includes a block 406 where an oxygen-free dielectric layer 142 is deposited over the first gate isolation trench 184-1 and the second gate isolation trench 184-2. In some embodiments, the oxygen-free dielectric layer 142 may include silicon nitride and may be deposited using CVD or ALD. As shown in FIG. 22, the deposited oxygen-free dielectric layer 142 may be deposited over the first gate isolation trench 184-1 and the second gate isolation trench 184-2. In the depicted embodiments, the oxygen-free dielectric layer 142 completely fills the first gate isolation trench 184-1 in the first device region 1000 and the second gate isolation trench 184-2 in the second device region 2000. In some instances, the oxygen-free dielectric layer 142 deposited at block 416 covers the top surface of the hard mask layer 170.

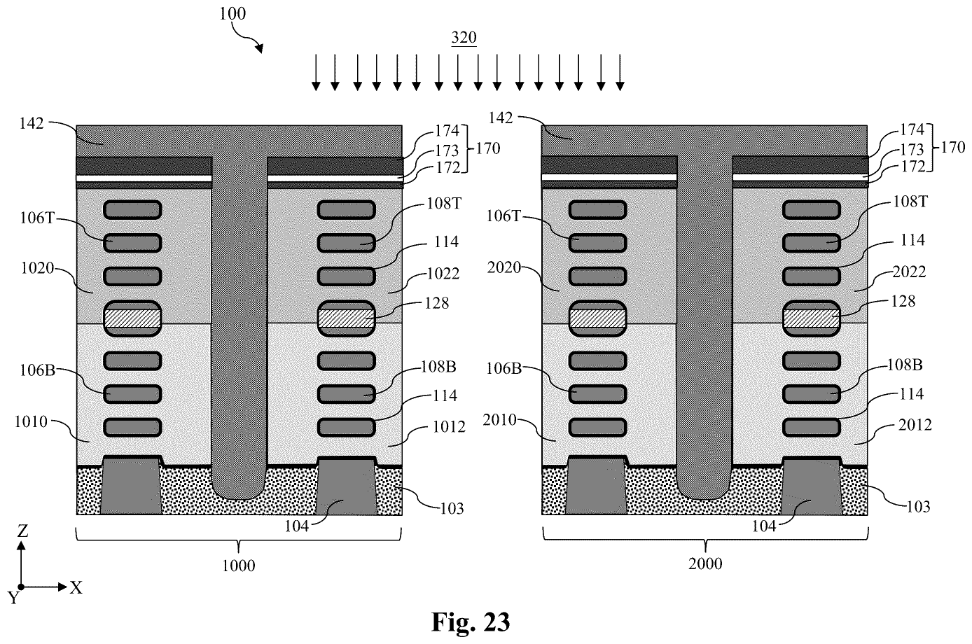

Referring to FIGS. 18 and 23, method 400 includes a block 408 where the first device region 1000 and the second device region 2000 is planarized in a planarization process 320 to thin down the oxygen-free dielectric layer 142. To form a smooth and planar top surface for the subsequent operations, block 408 planarizes the precursor structure 100 to reduce a thickness of the oxygen-free dielectric layer 142 over the top surface of the hard mask layer 170. In some instances, the planarization process 300 includes a chemical mechanical polishing (CMP) process.

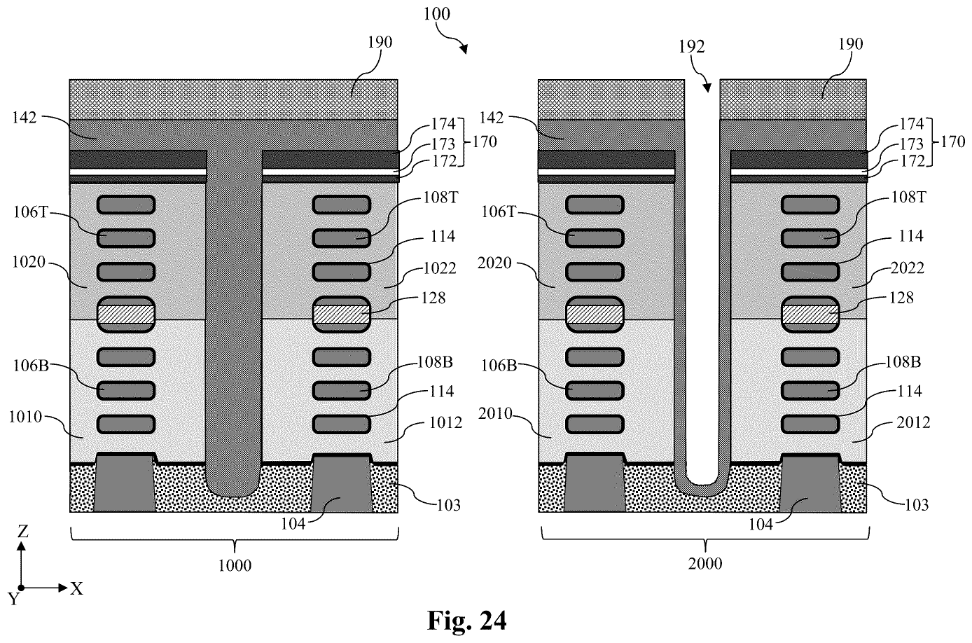

Referring to FIGS. 18 and 24, method 400 includes a block 410 where an inner trench 192 through the oxygen-free dielectric layer 142 in the second gate isolation trench 184-2. Operations at block 410 may include formation of a second patterned photoresist layer 190 and etching of the precursor structure 100 using the second patterned photoresist layer 190 as an etch mask. Referring to FIG. 24, the second photoresist layer 190 is deposited over the hard mask layer 170 using spin-on coating. At block 410, the second photoresist layer 190 is patterned by undergoes soft baking, mask aligning, exposure, post-exposure baking, photoresist developing, rinsing, drying (e.g., spin-drying and/or hard baking), other suitable lithography techniques, and/or combinations thereof. The second patterned photoresist layer 190 includes a mask opening directly over the second gate isolation trench 184-2 that is filled with the oxygen-free dielectric layer 142. An etching process, such as a dry etching (e.g., RIE etching), a wet etching, or a combination thereof, is performed to etch the oxygen-free dielectric layer 142 in the second gate isolation trench 184-2. Referring to FIG. 24, the etching at block 410 may form an inner trench 192 that extends vertically through oxygen-free dielectric layer 142 in the second gate isolation trench 184-2. As shown in FIG. 24, the inner trench 192 is spaced apart from sidewalls of the first top gate structure 2020 and the second top gate structure 2022, sidewalls of the first bottom gate structure 2010 and the second bottom gate structure 2012, and the isolation feature 103 by the oxygen-free dielectric layer. In some embodiments illustrated in FIG. 24, a bottom surface of the inner trench 192 may extend lower than a top surface of the isolation feature 103. After formation of the inner trench 192, any remaining second patterned photoresist layer 190 is removed from the precursor structure 100.

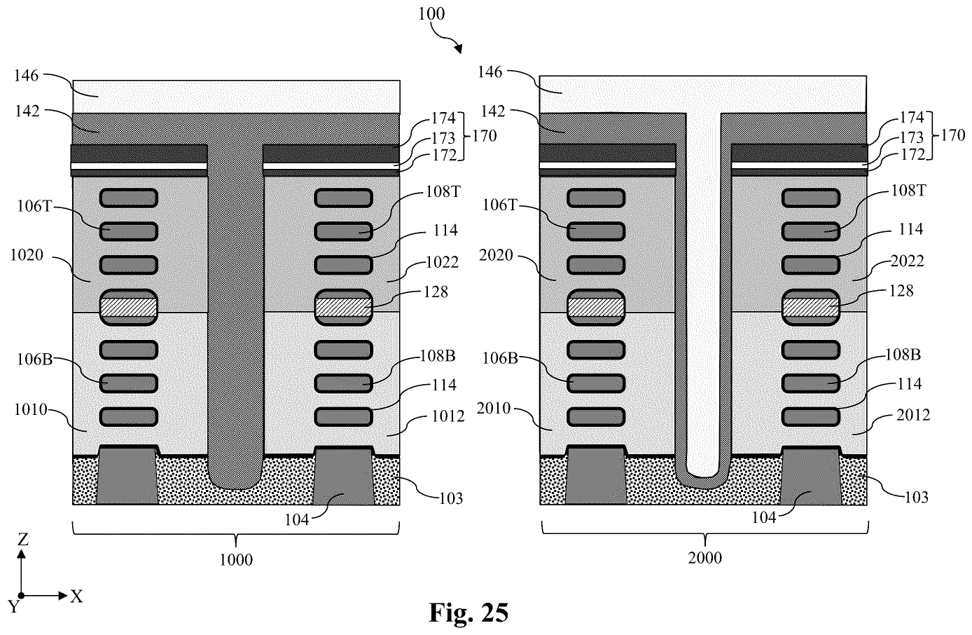

Referring to FIGS. 18 and 25, method 400 includes a block 412 where wherein an oxygen-containing dielectric layer 146 is deposited over the inner trench 192. In some embodiments, the oxygen-containing dielectric layer 146 may include silicon oxide and may be deposited using flowable CVD (FCVD), spin-on coating, CVD, or ALD. As shown in FIG. 25, at block 412, the oxygen-containing dielectric layer 146 not only completely fills the inner trench 192 in the second region 2000 and is deposited over a top surface of the oxygen-free dielectric layer 142 in the first device region 1000.

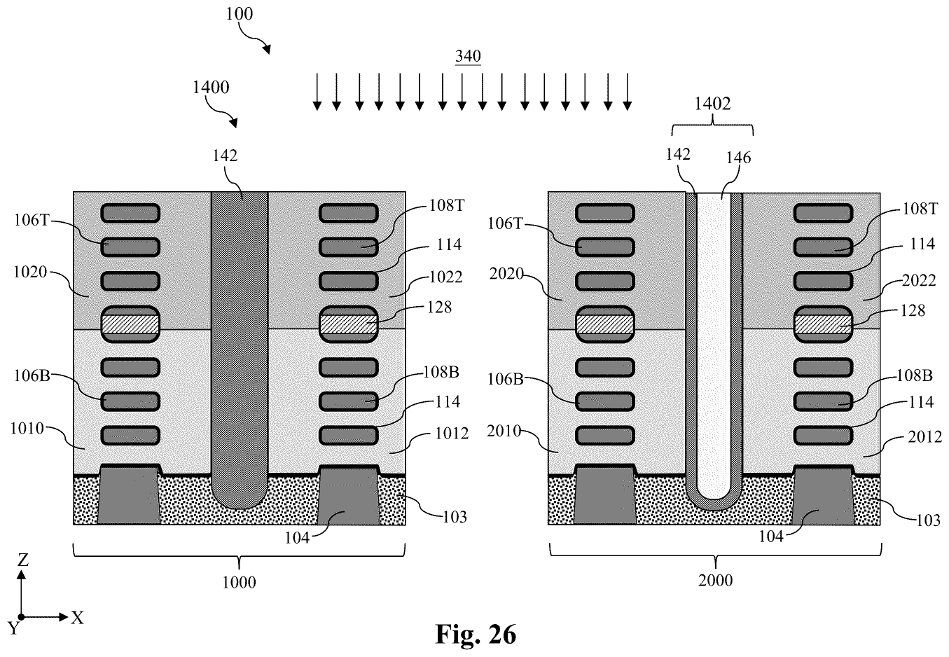

Referring to FIGS. 18 and 26, method 400 includes a block 414 where a planarization process 340 is performed to expose the top gate structures 120 and 122. The planarization process 340 may include a chemical mechanical polishing (CMP) process and functions to remove the excess oxygen-free dielectric layer 142 and the oxygen-containing dielectric 146 over top surfaces of the first top gate structure 1020 and the second top gate structure 1022 in the first device region 1000 and top surfaces of the first top gate structure 2020 and the second top gate structure 2022 in the second device region 2000. At this point, a first type gate isolation feature 1400 is formed in the first device region 1000 and a second type gate isolation feature 1402 is formed in the second device region 2000. The first type gate isolation feature 1400 is formed entirely of the oxygen-free dielectric layer 142 and help reduce oxygen diffusion into the gate structures that come in contact with it. The first type gate isolation feature 1400 is suitable to applications where device degradation is mainly caused by oxygen diffusion. The second type gate isolation feature 1402 includes both the oxygen-free dielectric layer 142 and the oxygen-containing dielectric layer 146. The second type gate isolation feature 1402 tends to have a smaller dielectric constant and is suitable for logic devices that require fast switching and low parasitic capacitance.

Referring to FIG. 18, method 400 includes a block 416 where further processes are performed. Such further processes may include formation of middle-end-of-line (MEOL) features and formation of back-end-of-line (BEOL) features. MEOL features may include frontside source/drain contacts, gate contact vias, backside source/drain contact via, and backside gate contact vias. BEOL features may include a frontside interconnect structure and a backside interconnect structure. The frontside interconnect structure includes a plurality of dielectric layers and a plurality of metal layers disposed in the plurality of dielectric layers. In some embodiments, the frontside interconnect structure includes between about 8 metal layers and about 20 metal layers. The backside interconnect structure includes a plurality of dielectric layers and a plurality of metal layers disposed in the plurality of dielectric layers. In some embodiments, the backside interconnect structure includes between about 2 metal layers and about 10 metal layers.

In one exemplary aspect, the present disclosure is directed to a semiconductor structure. The semiconductor structure includes a first active region and a second active region, a first gate structure disposed over the first active region, a second gate structure disposed over the second active region, and a gate isolation feature sandwiched between a sidewall of the first gate structure and a sidewall of the second gate structure. The gate isolation feature includes a first dielectric layer interfacing the sidewall of the first gate structure and the sidewall of the second gate structure, a diffusion barrier liner interfacing the first dielectric layer, and a second dielectric layer interfacing the diffusion barrier liner. The second dielectric layer is spaced apart from the first dielectric layer by the diffusion barrier liner and a composition of the first dielectric layer is different from a composition of the second dielectric layer.

In some embodiments, the diffusion barrier liner includes amorphous silicon, silicon carbonitride, amorphous carbon, or a polymer. In some embodiments, the first active region includes a first plurality of nanostructures, the second active region includes a second plurality of nanostructures, the first gate structure wraps around each of the first plurality of nanostructures, and the second gate structure wraps around each of the second plurality of nanostructures. In some embodiments, the semiconductor structure further includes a third active region over the first active region, a fourth active region over the second active region, a third gate structure disposed over the third active region, and a fourth gate structure disposed over the fourth active region. The gate isolation feature is also sandwiched between a sidewall of the third gate structure and a sidewall of the fourth gate structure. In some embodiments, the third gate structure is disposed over the first gate structure, and the fourth gate structure is disposed over the second gate structure. In some implementations, the first gate structure and the second gate structure include a p-type work function layer and the third gate structure and the fourth gate structure include an n-type work function layer. In some embodiments, the n-type work function layer includes titanium aluminum. In some embodiments, the diffusion barrier liner includes a first thickness and the first dielectric layer includes a second thickness greater than the first thickness. In some embodiments, a ratio of the first thickness to the second thickness is between about 1:4 and about 1:2. In some embodiments, the first thickness is between about 1 nm and about 1.5 nm and the second thickness is between about 3 nm and about 4 nm.

In another exemplary aspect, the present disclosure is directed to a semiconductor structure. The semiconductor structure includes a substrate having a memory device region and a logic device region, a first gate structure and a second gate structure over the memory device region, a third gate structure and a fourth gate structure over the logic device region, a first gate isolation feature sandwiched between the first gate structure and the second gate structure, and a second gate isolation feature sandwiched between the third gate structure and the fourth gate structure. A composition of the first gate isolation feature is different from a composition of the second gate isolation feature.

In some embodiments, the first gate isolation feature includes silicon nitride and the second gate isolation feature includes an outer layer interfacing a sidewall of the first gate structure and a sidewall of the second gate structure, and an inner layer spaced apart from the sidewall of the first gate structure and the sidewall of the second gate structure by the outer layer. A composition of the outer layer is different from a composition of the inner layer. In some embodiments, a dielectric constant of the outer layer is greater than a dielectric constant of the inner layer. In some embodiments, the outer layer includes silicon nitride and the inner layer includes silicon oxide. In some implementations, the semiconductor structure further includes a first top gate structure over the first gate structure, a second top gate structure over the second gate structure, a third top gate structure over the third gate structure, and a fourth top gate structure over the fourth gate structure. The first gate isolation feature extends between first top gate structure and the second top gate structure and the second gate isolation feature extends between the third top gate structure and the fourth top gate structure. In some embodiments, the first gate structure, the second gate structure, the third gate structure, and the fourth gate structure include a p-type work function metal layer and the first top gate structure, the second top gate structure, the third top gate structure, and the fourth top gate structure include an n-type work function metal layer.

In yet another exemplary aspect, the present disclosure is directed to a method. The method includes providing a precursor structure that includes a substrate including a first device region and a second device region, a first bottom gate structure over the first device region, a first top gate structure over the first bottom gate structure, a first hard mask layer over the first top gate structure, a second bottom gate structure over the second device region, a second top gate structure over the second bottom gate structure, and a second hard mask layer over the second top gate structure, forming a first trench through the first hard mask layer, the first top gate structure, and the first bottom gate structure, forming a second trench through the second hard mask layer, the second top gate structure, and the second bottom gate structure, depositing a first dielectric layer over the first device region and the second device region to fill the first trench and the second trench, forming a patterned mask over the first device region and the second device region while a portion of the first dielectric layer over the second trench is exposed through an opening of the patterned mask, etching the first dielectric layer in the second trench to form an inner trench, removing the patterned mask, depositing a second dielectric layer over the inner trench, and after depositing of the second dielectric layer, planarizing the precursor structure to expose top surfaces of the first top gate structure and the second top gate structure and to form a first gate cut feature in the first trench and a second gate cut feature in the second trench. A composition of the first dielectric layer is different from a composition of the second dielectric layer.

In some embodiments, the first dielectric layer includes silicon nitride and the second dielectric layer includes silicon oxide. In some implementations, the first bottom gate structure and the second bottom gate structure include a p-type work function metal layer and the first top gate structure and the second top gate structure include an n-type work function metal layer. In some embodiments, the first gate cut feature is disposed between a first stack of nanostructures and a second stack of nanostructures, the first gate cut feature divides the first bottom gate structure into a first gate segment and a second gate segment, the first gate segment wraps around each of the first stack of nanostructures, and the second gate segment wraps around each of the second stack of nanostructures.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first active region and a second active region;
a first gate structure disposed over the first active region;
a second gate structure disposed over the second active region; and
a gate isolation feature sandwiched between a sidewall of the first gate structure and a sidewall of the second gate structure,
wherein the gate isolation feature comprises:
a first dielectric layer interfacing the sidewall of the first gate structure and the sidewall of the second gate structure,
a diffusion barrier liner interfacing the first dielectric layer, and
a second dielectric layer interfacing the diffusion barrier liner,
wherein the second dielectric layer is spaced apart from the first dielectric layer by the diffusion barrier liner,
wherein a composition of the first dielectric layer is different from a composition of the second dielectric layer.

2. The semiconductor structure of claim 1, wherein the diffusion barrier liner comprises amorphous silicon, silicon carbonitride, amorphous carbon, or a polymer.

3. The semiconductor structure of claim 1,
wherein the first active region comprises a first plurality of nanostructures,
wherein the second active region comprises a second plurality of nanostructures,
wherein the first gate structure wraps around each of the first plurality of nanostructures,
wherein the second gate structure wraps around each of the second plurality of nanostructures.

4. The semiconductor structure of claim 1, further comprising:
a third active region over the first active region;
a fourth active region over the second active region;
a third gate structure disposed over the third active region; and
a fourth gate structure disposed over the fourth active region,
wherein the gate isolation feature is also sandwiched between a sidewall of the third gate structure and a sidewall of the fourth gate structure.

5. The semiconductor structure of claim 4,
wherein the third gate structure is disposed over the first gate structure, and
wherein the fourth gate structure is disposed over the second gate structure.

6. The semiconductor structure of claim 5,
wherein the first gate structure and the second gate structure comprise a p-type work function layer,
wherein the third gate structure and the fourth gate structure comprise an n-type work function layer.

7. The semiconductor structure of claim 6, wherein the n-type work function layer comprises titanium aluminum.

8. The semiconductor structure of claim 1,
wherein the diffusion barrier liner comprises a first thickness,
wherein the first dielectric layer comprises a second thickness greater than the first thickness.

9. The semiconductor structure of claim 8, wherein a ratio of the first thickness to the second thickness is between about 1:4 and about 1:2.

10. The semiconductor structure of claim 8,
wherein the first thickness is between about 1 nm and about 1.5 nm,
wherein the second thickness is between about 3 nm and about 4 nm.

11. A semiconductor structure, comprising:
a substrate having a memory device region and a logic device region;
a first gate structure and a second gate structure over the memory device region;
a third gate structure and a fourth gate structure over the logic device region;
a first gate isolation feature sandwiched between the first gate structure and the second gate structure; and
a second gate isolation feature sandwiched between the third gate structure and the fourth gate structure,
wherein a composition of the first gate isolation feature is different from a composition of the second gate isolation feature.

12. The semiconductor structure of claim 11,
wherein the first gate isolation feature comprises silicon nitride,
wherein the second gate isolation feature comprises:
an outer layer interfacing a sidewall of the first gate structure and a sidewall of the second gate structure, and
an inner layer spaced apart from the sidewall of the first gate structure and the sidewall of the second gate structure by the outer layer,
wherein a composition of the outer layer is different from a composition of the inner layer.

13. The semiconductor structure of claim 12, wherein a dielectric constant of the outer layer is greater than a dielectric constant of the inner layer.

14. The semiconductor structure of claim 12, wherein the outer layer comprises silicon nitride and the inner layer comprises silicon oxide.

15. The semiconductor structure of claim 11, further comprising:
a first top gate structure over the first gate structure;
a second top gate structure over the second gate structure;
a third top gate structure over the third gate structure; and
a fourth top gate structure over the fourth gate structure,
wherein the first gate isolation feature extends between first top gate structure and the second top gate structure,
wherein the second gate isolation feature extends between the third top gate structure and the fourth top gate structure.

16. The semiconductor structure of claim 15,
wherein the first gate structure, the second gate structure, the third gate structure, and the fourth gate structure comprise a p-type work function metal layer,
wherein the first top gate structure, the second top gate structure, the third top gate structure, and the fourth top gate structure comprise an n-type work function metal layer.

17. A method, comprising:
providing a precursor structure that includes:
a substrate comprising a first device region and a second device region,
a first bottom gate structure over the first device region,
a first top gate structure over the first bottom gate structure,
a first hard mask layer over the first top gate structure,
a second bottom gate structure over the second device region,
a second top gate structure over the second bottom gate structure, and
a second hard mask layer over the second top gate structure,
forming a first trench through the first hard mask layer, the first top gate structure, and the first bottom gate structure;
forming a second trench through the second hard mask layer, the second top gate structure, and the second bottom gate structure;
depositing a first dielectric layer over the first device region and the second device region to fill the first trench and the second trench;
forming a patterned mask over the first device region and the second device region while a portion of the first dielectric layer over the second trench is exposed through an opening of the patterned mask;
etching the first dielectric layer in the second trench to form an inner trench;
removing the patterned mask;
depositing a second dielectric layer over the inner trench; and
after depositing of the second dielectric layer, planarizing the precursor structure to expose top surfaces of the first top gate structure and the second top gate structure and to form a first gate cut feature in the first trench and a second gate cut feature in the second trench,
wherein a composition of the first dielectric layer is different from a composition of the second dielectric layer.

18. The method of claim 17,
wherein the first dielectric layer comprises silicon nitride,
wherein the second dielectric layer comprises silicon oxide.

19. The method of claim 17,
wherein the first bottom gate structure and the second bottom gate structure comprise a p-type work function metal layer,
wherein the first top gate structure and the second top gate structure comprise an n-type work function metal layer.

20. The method of claim 17,
wherein the first gate cut feature is disposed between a first stack of nanostructures and a second stack of nanostructures,
wherein the first gate cut feature divides the first bottom gate structure into a first gate segment and a second gate segment,
wherein the first gate segment wraps around each of the first stack of nanostructures,
wherein the second gate segment wraps around each of the second stack of nanostructures.
